(19) United States
(12) Patent Application Publication
(10) Pub. No.: US 2025/0019859 A1
(43) Pub. Date: Jan. 16, 2025

(54) FLOW GUIDE CYLINDER LIFTING ASSEMBLY AND SUSPENDED FLOW GUIDE CYLINDER CONTAINING SAME

(71) Applicant: TCL ZHONGHUAN RENEWABLE ENERGY TECHNOLOGY CO., LTD., Tianjin (CN)

(72) Inventors: Mingyang GONG, Tianjin (CN); Wenxia ZHANG, Tianjin (CN); Qian GUO, Tianjin (CN); Shengli WANG, Tianjin (CN); Xuebing KANG, Tianjin (CN); Yanjie ZHOU, Tianjin (CN); Peng HAN, Tianjin (CN); Jinliang QIAO, Tianjin (CN); Lin WANG, Tianjin (CN); Haoping SHEN, Tianjin (CN)

(73) Assignee: TCL ZHONGHUAN RENEWABLE ENERGY TECHNOLOGY CO., LTD., Tianjin (CN)

(21) Appl. No.: 18/548,078

(22) PCT Filed: Jul. 31, 2023
(86) PCT No.: PCT/CN2023/110399

§ 371 Date: Aug. 26, 2023

(30) Foreign Application Priority Data
Aug. 31, 2022 (CN) 202222302923.5

(51) Int. Cl. C30B 15/30

(52) U.S. Cl. CPC C30B 15/30

(57) ABSTRACT

The present disclosure provides a flow guide cylinder lifting assembly, including a flow guide cylinder lifting component disposed on a water-cooling lateral arm and a lifting bolt, wherein the lifting bolt is disposed in the flow guide cylinder lifting component, a lower end of the lifting bolt extends downward through an opening of an upper heat-insulating cover of the flow guide cylinder, a lifting nut is disposed at an upper end of the lifting bolt, and the lifting nut is matched to the lifting bolt to raise or lower the flow guide cylinder.

### CROSS-REFERENCE TO RELATED APPLICATION

The present disclosure claims priority to and the benefit of Chinese Patent Application No. 202222302923.5, filed on Aug. 31, 2022, the disclosure of which is incorporated herein by reference in its entirety.

### TECHNICAL FIELD

The present disclosure relates to the field of Czochralski single crystal equipment, and particularly relates to a lifting assembly for a flow guide cylinder and a novel suspended flow guide cylinder containing the same.

### BACKGROUND

Czochralski process for growth of monocrystalline silicon is the most widely used technology for producing monocrystalline silicon at present. With the intensification of market competition, the requirements for the single crystal quality have become more stringent, especially for the quality of large-sized single crystal, so existing monocrystalline silicon manufacturers need to prepare monocrystalline silicon with higher quality. In order to maintain a normal growth of the single crystal, a flow guide cylinder needs to be added. Therefore, the flow guide cylinder has become one of the critical systems in current Czochralski single crystal furnaces.

At present, a conventional lifting mode of the flow guide cylinder is performed by means of outer lifting pins. However, since the center of gravity of the flow guide cylinder is in the center thereof, coupled with the use of an upper heat-insulating cover with a larger diameter, the flow guide cylinder is deformed significantly after being raised and lowered to cause potential position deviation and poor alignment thereof, thereby affecting the judgment of normal position of a crucible and the crystal formation. In addition, the relatively large horizontal deviation of the flow guide cylinder may lead to unequal distances between the lower edge of the flow guide cylinder and the liquid level, and affect the improvement of pulling speed of the single crystal. Moreover, it is required to remove the upper thermal insulating cover during cleaning of the furnace cover in each stopped furnace, and this causes labor and time consumed.

### SUMMARY

The present disclosure provides a lifting assembly for a flow guide cylinder and a novel suspended flow guide cylinder containing the same to solve the problems in the prior art that the flow guide cylinder is deformed significantly after being raised and lowered to cause potential position deviation and poor alignment thereof, thereby resulting in unequal distances between the lower edge of the flow guide cylinder and the liquid level, affecting the judgment of normal position of the crucible and the crystal formation, and affecting the improvement of pulling speed for single crystal bars. Moreover, the present disclosure also solves the problem that it is required to remove the upper thermal insulating cover during cleaning of the furnace cover in each stopped furnace and causes labor and time consumed.

In order to solve the above technical problems, the present disclosure provides a lifting assembly for a flow guide cylinder, which includes a flow guide cylinder lifting component mounted on a water-cooling lateral arm and a lifting bolt, wherein the lifting bolt is disposed in the flow guide cylinder lifting component, a lower end of the lifting bolt extends downward through an opening of an upper heat-insulating cover of the flow guide cylinder, a lifting nut is disposed at an upper end of the lifting bolt, and the lifting nut is matched to the lifting bolt to raise or lower the flow guide cylinder.

In some embodiment of the present disclosure, a supporting cap is disposed on the lower end of the lifting bolt extending through the upper heat-insulating cover of the flow guide cylinder, and a size of the supporting cap is larger than a diameter of the opening of the upper heat-insulating cover of the flow guide cylinder.

In some embodiment of the present disclosure, the flow guide cylinder lifting component includes a flow guide cylinder lifting clamp extending proximodistally along a direction perpendicular to a center axis of the water-cooling lateral arm, a distal end of the flow guide cylinder lifting clamp is connected to the water-cooling lateral arm, a groove is formed in a proximal end of the flow guide cylinder lifting clamp and configured to receive the lifting bolt, a positioning plate is disposed on a side of the flow guide cylinder lifting clamp close to the water-cooling lateral arm and is in contact with the water-cooling lateral arm, and the positioning plate is capable to control an angle between the flow guide cylinder lifting clamp and the water-cooling lateral arm.

In some embodiment of the present disclosure, an end of the groove away from the water-cooling lateral arm is open to form a U-shaped groove.

In some embodiment of the present disclosure, two sides of the groove are arcuate matching a surface arc of the lifting bolt.

In some embodiment of the present disclosure, an upper surface of the positioning plate is connected to a surface of the flow guide cylinder lifting clamp close to the water-cooling lateral arm, a side surface of the positioning plate is in contact with the water-cooling lateral arm, and the upper surface of the positioning plate is perpendicular to the side surface of the positioning plate.

In some embodiment of the present disclosure, protrusions are further disposed at the proximal end of the flow guide cylinder lifting clamp away from the water-cooling lateral arm and configured to prevent the lifting bolt from falling out of the flow guide cylinder lifting clamp.

In some embodiment of the present disclosure, a diameter of the lifting nut is at least greater than a spacing distance between two sides of the groove.

Another aspect of the present disclosure providers a novel suspended flow guide cylinder, which includes the flow guide cylinder lifting assembly according to the above technical solution.

In some embodiment of the present disclosure, a maximum diameter of the flow guide cylinder is D, and a diameter of an upper heat-insulating cover at the top of the flow guide is larger than D by 40 mm to 60 mm.

The above technical solutions of the present disclosure replace the lifting mode of the flow guide cylinder, adjust the position of the flow guide cylinder more accurately by matching of the lifting bolt and the flow guide cylinder lifting component, thereby reducing the deviation value of the flow guide cylinder from 11% to 5%, reducing the position deviation of the crucible at a stable temperature, reducing the deformation amount, improving the alignment of the thermal field, reducing the deviation of the flow guide cylinder, improving the accuracy of the liquid level judgment, improving the crystallization rate, and improving the workshop yield.

With the above technical solutions, the furnace cover in the suspended flow guide cylinder can be cleaned directly, and the flow guide cylinder is not required to be disassembled in each furnace to clean the cover, thereby saving human labor, time for disassembly to clean, and improving the working efficiency.

### BRIEF DESCRIPTION OF THE DRAWINGS

In order to more clearly illustrate the technical solutions in the embodiments of the present disclosure, reference will now be made briefly below to the accompanying drawings required for the description of the embodiments. It will be apparent that the accompanying drawings in the following description are merely some of the embodiments of the present disclosure, and other drawings may be obtained based on these drawings to those skilled in the art without involving any inventive effort.

FIG. 1 is a schematic structural diagram of a flow guide cylinder lifting assembly according to an embodiment of the present disclosure.

FIG. 2 is a schematic structural diagram of a flow guide cylinder lifting component according to an embodiment of the present disclosure.

### LIST OF REFERENCE NUMBERS

1: Flow guide cylinder lifting clamp; 2: Groove; 3: Protrusion; 4: Positioning plate; 5: Water-cooling lateral arm; 6: Lifting bolt; 7: Lifting nut; 8: Upper heat-insulating cover; 9: Flow guide cylinder; 10: Supporting cap.

### DETAILED DESCRIPTION OF THE EMBODIMENTS

The present disclosure will now be further described with reference to the embodiments and the accompanying drawings.

In the description of embodiments of the present disclosure, it is to be understood that orientations or position relationships indicated by the terms “top”, “bottom”, and the like are based on orientations or position relationships illustrated in the drawings. The terms are used to facilitate and simplify the description of the present disclosure, rather than indicate or imply that the devices or elements referred to herein are required to have specific orientations or be constructed or operate in the specific orientations. Accordingly, the terms should not be construed as limiting the present disclosure. In the description of the present disclosure, it should be noted that unless otherwise clearly defined and limited, the terms “dispose” and “connect” should be interpreted broadly. For example, the terms may refer to a fixed connection, a detachable connection, or an integral connection; the terms may further refer to a direct connection, an indirect connection through an intermediary, or an interconnection between two elements. Those skilled in the art can understand the specific meanings of the above-mentioned terms in the present disclosure according to circumstances.

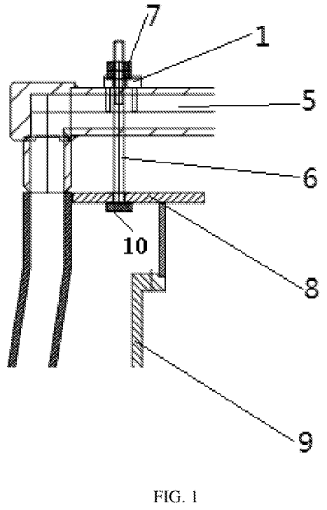

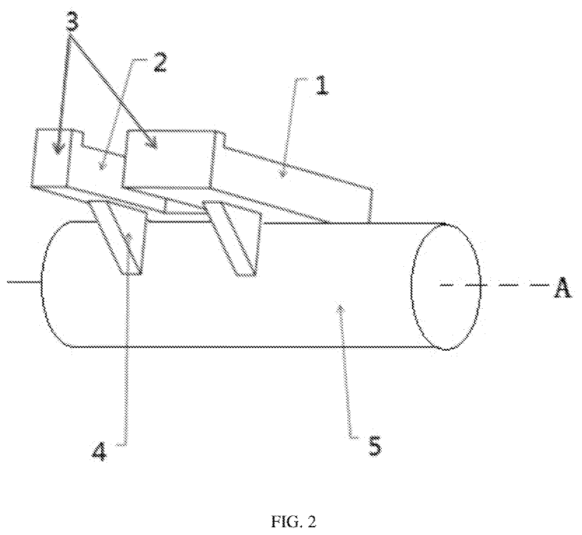

Referring to FIG. 1, which is a schematic structural diagram of a flow guide cylinder lifting assembly, and referring to FIG. 2, which is a schematic structural diagram of a flow guide cylinder lifting component, the present disclosure provides a flow guide cylinder lifting assembly, which includes a flow guide cylinder lifting component disposed on a water-cooling lateral arm 5 and a lifting bolt 6. The lifting bolt 6 is disposed in the flow guide cylinder lifting component. A lower end of the lifting bolt 6 extends downward through an opening of an upper heat-insulating cover 8 of the flow guide cylinder, a lifting nut 7 is disposed at an upper end of the lifting bolt 6 to fix the lifting bolt 6, and the lifting nut 7 is matched to the lifting bolt 6 to raise or lower the flow guide cylinder along the lifting bolt 6.

Specifically, a supporting cap 10 is disposed on the lower end of the lifting bolt 6 extending through the upper heat-insulating cover 8 of the flow guide cylinder. A size of the supporting cap 10 is larger than a diameter of the opening of the upper heat-insulating cover 8 penetrated by the lifting bolt 6, so as to ensure that the upper heat-insulating cover 8 of the flow guide cylinder and a flow guide cylinder 9 are suspended stably. A shape of the supporting cap is not limited, and is generally set as a circular shape. It only needs to ensure that the size of the supporting cap is slightly larger than the diameter of the opening of the upper heat-insulating cover 8 of the flow guide cylinder, so that the upper heat-insulating cover 8 of the flow guide cylinder does not fall off, and can be moved up and down along the lifting bolt 6.

The lifting nut 7 is disposed on the upper end of the lifting bolt 6 opposite to the supporting cap 10, and is configured to fix the lifting bolt 6. When the flow guide cylinder 9 needs to be raised, the lifting bolt 6 together with the upper heat-insulating cover 8 and the flow guide cylinder 9 is first raised to a target position, and then is stably fixed at the target position by adjusting the lifting nut 7, thereby fixing the flow guide cylinder 9 at the target position. Therefore, a distance between the flow guide cylinder and a crucible can be adjusted using the lifting nut 7 in cooperation with the lifting bolt 6, so as to reduce a position deviation of the crucible at a stable temperature, and improve judgment accuracy for the liquid level.

The flow guide cylinder lifting component includes a flow guide cylinder lifting clamp 1. As shown in FIG. 2, the flow guide cylinder lifting clamp 1 extends proximodistally along a direction perpendicular to a center axis A of the water-cooling lateral arm 5, a distal end of the flow guide cylinder lifting clamp 1 is connected to the water-cooling lateral arm 5, a groove 2 is formed in a proximal end of the flow guide cylinder lifting clamp 1 and configured to receive the lifting bolt 6.

The flow guide cylinder lifting clamp 1 is made of stainless steel and is suitable for all thermal fields. The flow guide cylinder lifting clamp 1 is U-shaped, and is located on a top surface of the water-cooling lateral arm 5 and configured to support the lifting bolts 6. The flow guide cylinder lifting clamp 1 is configured to raise or lower the flow guide cylinder in cooperation with the lifting bolt 6.

In some practicable embodiments, the number of the flow guide cylinder lifting clamps 1 is same as the number of the lifting bolts 6.

A positioning plate 4 is disposed on a side of the flow guide cylinder lifting clamp 1 close to the water-cooling lateral arm 5, and the positioning plate 4 is in contact with the water-cooling lateral arm 5. The positioning plate 4 can control an angle between the flow guide cylinder lifting clamp 1 and the water-cooling lateral arm 5 to maintain the flow guide cylinder lifting clamp 1 in a horizontal direction.

Specifically, a length of the flow guide cylinder lifting clamp 1 is X, a diameter of the water-cooling lateral arm 5 is Y, and 1.5Y<X≤3Y. That is, the length of the flow guide cylinder lifting clamp 1 is greater than 1.5 times the diameter of the water-cooling lateral arm 5 and less than or equal to 3 times the diameter of the water-cooling lateral arm 5. For different diameters of the water-cooling lateral arm 5 in different thermal fields, it only needs to set the length of the flow guide cylinder lifting clamp 1 in this range. In some practicable embodiments, the flow guide cylinder lifting clamp 1 may be set as a retractable lifting clamp. Although the device may be reused for different thermal fields, the flow guide cylinder lifting clamp 1 is easily bent when it is too long, resulting in reduction of the raising accuracy of the flow guide cylinder and reduction of the single crystal quality.

The groove 2 is formed in the flow guide cylinder lifting clamp 1, and an end of the groove 2 away from the water-cooling lateral arm 5 is open. That is, the end of the groove 2 away from the water-cooling lateral arm 5 is not enclosed, so that the flow guide cylinder lifting clamp 1 is U-shaped as a whole. In fact, the groove 2 is also U-shaped, and a size of the groove 2 is matched with a size of the lifting bolt 6 entering the inside of the groove 2. The size of the groove 2 is typically slightly larger than a diameter of the middle portion of the lifting bolt 6, and less than the maximum diameter of the lower end of the lifting bolt 6.

In some practicable embodiments, a diameter of the opening of the upper heat-insulating cover 8 (for example, carbon-carbon heat-insulating cover) of the flow guide cylinder is d, which is equal to the diameter of the lower end of the lifting bolt 6, a spacing distance between two sides of the groove 2 is greater than d by 3 mm, and a depth of the groove 2 is 4 times to 6 times d. Therefore, the groove 2 matches with the diameter of the lifting bolt 6, but also can provide sufficient moving space for the lifting bolt 6.

In some practicable embodiments, in order to better match the lifting bolts 6, both sides of the groove 2 are formed as arc-shaped sides. This configuration enables the lifting bolt 6 to be more perfectly received in the groove 2, and prevents the lifting bolt 6 from falling out of the flow guide cylinder lifting component during movement.

An upper surface of the positioning plate 4 is connected to a surface of the flow guide cylinder lifting clamp 1 close to the water-cooling lateral arm 5. A side surface of the positioning plate 4 is in contact with the water-cooling lateral arm 5. The upper surface connected to the flow guide cylinder lifting clamp 1 is perpendicular to the side surface contacted with the water-cooling lateral arm 5. Generally, the upper surface of the positioning plate 4 is welded to the surface (for example, bottom surface) of the flow guide cylinder lifting clamp 1 close to the water-cooling lateral arm 5, and the side surface contacted with the water-cooling lateral arm 5 is perpendicular to the upper surface of the positioning plate 4. There may be one or more positioning plates 4, for example, two positioning plates 4, as shown in FIG. 2. Each of the positioning plates 4 may be an isosceles right triangle-shaped plate, or a vertical angle-steel, provided that the flow guide cylinder lifting clamp 1 is maintained in a horizontal direction.

In some practicable embodiments, a length of the side surface of the positioning plate 4 connected to the water-cooling lateral arm 5 is larger than one half of the diameter of the water-cooling lateral arm 5, in order to ensure a stable fixing of the flow guide cylinder lifting clamp 1.

In some practicable embodiments, protrusions 3 for preventing the lifting bolt 6 from falling are disposed at the proximal end of the flow guide cylinder lifting clamp 1 away from the water-cooling lateral arm 5. At least one protrusion 3 is disposed on the flow guide cylinder lifting clamp 1 to block the falling of the lifting bolt 6. In this embodiment, the number of the protrusions 3 is two. A shape of the protrusions 3 is not limited, provided that the falling of the lifting bolt 6 can be blocked. Typically, rectangular protrusions may be selected commonly for practical and aesthetic purposes.

In some practicable embodiments, a protruding height of the protrusions 3 with respect to the flow guide cylinder lifting clamp 1 is 3-5 mm, and can be adjusted according to the lifting bolts 6 used in different thermal fields.

In a novel flow guide cylinder containing the above flow guide cylinder lifting assembly, the maximum diameter of the flow guide cylinder 9 is D, then the diameter of the upper heat-insulating cover 8 of the flow guide cylinder at the top of the flow guide cylinder 9 is greater than D by 40 mm to 60 mm. Compared with the existing upper heat-insulating cover of the flow guide cylinder, the diameter of the upper heat-insulating cover 8 according to the present disclosure is reduced by about 500 mm, thereby reducing cost of the thermal field. In addition, due to the suspension arrangement of the flow guide cylinder, it is not necessary to disassemble and remove the flow guide cylinder for each furnace to clean the furnace cover, and so that the flow guide cylinder 9 can be directly cleaned, thereby saving human the labor and time for disassembly and cleaning, and improving the operation efficiency.

The embodiments of the present disclosure have been described in detail above, but the description is only a preferred embodiment of the present disclosure and should not be considered as limiting the scope of the present disclosure. All modifications and improvements made in accordance with the scope of the present disclosure shall still fall within the scope of the present disclosure.

What is claimed is:

1. A lifting assembly for a flow guide cylinder, comprising a flow guide cylinder lifting component disposed on a water-cooling lateral arm and a lifting bolt, wherein the lifting bolt is disposed in the flow guide cylinder lifting component, a lower end of the lifting bolt extends downward through an opening of an upper heat-insulating cover of the flow guide cylinder, a lifting nut is disposed at an upper end of the lifting bolt, and the lifting nut is matched to the lifting bolt to raise or lower the flow guide cylinder.

2. The lifting assembly for the flow guide cylinder according to claim 1, wherein a supporting cap is disposed on the lower end of the lifting bolt extending through the upper heat-insulating cover of the flow guide cylinder, and a size of the supporting cap is larger than a diameter of the opening of the upper heat-insulating cover of the flow guide cylinder.

3. The lifting assembly for the flow guide cylinder according to claim 1, wherein the flow guide cylinder lifting component comprises a flow guide cylinder lifting clamp extending proximodistally along a direction perpendicular to a center axis of the water-cooling lateral arm, a distal end of the flow guide cylinder lifting clamp is connected to the water-cooling lateral arm, a groove is formed in a proximal end of the flow guide cylinder lifting clamp and configured to receive the lifting bolt, a positioning plate is disposed on a side of the flow guide cylinder lifting clamp close to the water-cooling lateral arm and is in contact with the water-cooling lateral arm, and the positioning plate is capable to control an angle between the flow guide cylinder lifting clamp and the water-cooling lateral arm.

4. The lifting assembly for the flow guide cylinder according to claim 2, wherein the flow guide cylinder lifting component comprises a flow guide cylinder lifting clamp extending proximodistally along a direction perpendicular to a center axis of the water-cooling lateral arm, a distal end of the flow guide cylinder lifting clamp is connected to the water-cooling lateral arm, a groove is formed in a proximal end of the flow guide cylinder lifting clamp and configured to receive the lifting bolt, a positioning plate is disposed on a side of the flow guide cylinder lifting clamp close to the water-cooling lateral arm and is in contact with the water-cooling lateral arm, and the positioning plate is capable to control an angle between the flow guide cylinder lifting clamp and the water-cooling lateral arm.

5. The lifting assembly for the flow guide cylinder according to claim 3, wherein an end of the groove away from the water-cooling lateral arm is open to form a U-shaped groove.

6. The lifting assembly for the flow guide cylinder according to claim 4, wherein an end of the groove away from the water-cooling lateral arm is open to form a U-shaped groove.

7. The lifting assembly for the flow guide cylinder according to claim 5, wherein two sides of the groove are arcuate matching a surface arc of the lifting bolt.

8. The lifting assembly for the flow guide cylinder according to claim 6, wherein two sides of the groove are arcuate matching a surface arc of the lifting bolt.

9. The lifting assembly for the flow guide cylinder according to claim 3, wherein an upper surface of the positioning plate is connected to a surface of the flow guide cylinder lifting clamp close to the water-cooling lateral arm, a side surface of the positioning plate is in contact with the water-cooling lateral arm, and the upper surface of the positioning plate is perpendicular to the side surface of the positioning plate.

10. The lifting assembly for the flow guide cylinder according to claim 4, wherein an upper surface of the positioning plate is connected to a surface of the flow guide cylinder lifting clamp close to the water-cooling lateral arm, a side surface of the positioning plate is in contact with the water-cooling lateral arm, and the upper surface of the positioning plate is perpendicular to the side surface of the positioning plate.

11. The lifting assembly for the flow guide cylinder according to claim 3, further comprising protrusions disposed at the proximal end of the flow guide cylinder lifting clamp away from the water-cooling lateral arm and configured to prevent the lifting bolt from falling out of the flow guide cylinder lifting clamp.

12. The lifting assembly for the flow guide cylinder according to claim 4, further comprising protrusions disposed at the proximal end of the flow guide cylinder lifting clamp away from the water-cooling lateral arm and configured to prevent the lifting bolt from falling out of the flow guide cylinder lifting clamp.

13. The lifting assembly for the flow guide cylinder according to claim 3, wherein a diameter of the lifting nut is at least greater than a spacing distance between two sides of the groove.

14. The lifting assembly for the flow guide cylinder according to claim 4, wherein a diameter of the lifting nut is at least greater than a spacing distance between two sides of the groove.

15. A suspended flow guide cylinder comprising the lifting assembly for the flow guide cylinder according to claim 1, wherein the lifting assembly comprises a flow guide cylinder lifting component mounted on a water-cooling lateral arm and a lifting bolt, the lifting bolt is disposed in the flow guide cylinder lifting component, a lower end of the lifting bolt extends downward through an opening of an upper heat-insulating cover of the flow guide cylinder, a lifting nut is disposed at an upper end of the lifting bolt, and the lifting nut is matched to the lifting bolt to raise or lower the flow guide cylinder.

16. The suspended flow guide cylinder according to claim 15, wherein a maximum diameter of the flow guide cylinder is D, and a diameter of an upper heat-insulating cover at the top of the flow guide cylinder is larger than D by 40 mm to 60 mm.
